(19) United States
(12) Patent Application Publication
(10) Pub. No.: US 2009/0115641 A1
(43) Pub. Date: May 7, 2009

(54) POSITIONING STRUCTURE FOR EXTERNAL KEYPAD ASSEMBLY

(75) Inventors: XU-RI ZHANG, Shenzhen (CN); YE LIU, Shenzhen (CN); RUI-HAO CHEN, Shenzhen (CN)

Correspondence Address: PCE INDUSTRY, INC.;ATT. Steven Reiss, 458 E. LAMBERT ROAD, FULLERTON, CA, 92835, US

(73) Assignees: SHENZHEN FUTAIHONG PRECISION INDUSTRY CO., LTD., ShenZhen City (CN); SUTECH TRADING LIMITED, Tortola (VG)

(21) Appl. No.: 11/964,863

(22) Filed: Dec. 27, 2007

(30) Foreign Application Priority Data
Nov. 5, 2007 (CN) 200710202392.X

(51) Int. Cl. H03K 17/94; G06F 1/16

(52) U.S. Cl. 341/22; 341/23

(57) ABSTRACT

A positioning structure (30) for an accessory keypad assembly (20) is provided. The accessory keypad assembly includes an upper shell (21) and a lower shell (22). The positioning structure includes a first mounting portion (231), a second mounting portion (232), a third mounting portion (233), a first positioning block (234), a second positioning block (235), and an elastic member (236). The third mounting portion extends from the second mounting portion and is located between the first and second mounting portions. The first positioning block is rotatably mounted on the first mounting portion. The second positioning block is rotatably and slidably mounted on the second mounting portion. The elastic member has one end mounted on the third mounting portion and the other end mounted on the second positioning block.

### BACKGROUND OF THE INVENTION

1. Field of the Invention

The present invention relates to positioning structures, and particularly to a positioning structure for an external keypad for a portable electronic device.

2. Description of related art

An external keypad assembly is usually assembled with a portable electronic device (e.g., a mobile phone). The external keypad assembly is often positioned on the portable electronic device and communicates with the portable electronic device with wires/cables or wirelessly.

However, users may feel uncomfortable to operate the external keypad assembly, in case that the external keypad assembly may be unstable when positioned on the portable electronic device.

Therefore, a heretofore-unaddressed need exists in the art to address the aforementioned deficiencies and inadequacies.

### SUMMARY

In present aspect, a positioning structure for an external keypad assembly is provided. The external keypad assembly includes an upper shell and a lower shell. The positioning structure includes a first mounting portion, a second mounting portion, a third mounting portion, a first positioning block, a second positioning block, and an elastic member. The first mounting portion is defined in the lower shell of the keypad assembly. The second mounting portion is defined in the lower shell of the keypad assembly. The third mounting portion extends from the second mounting portion and is located between the first mounting portion and second mounting portion. The first positioning block is rotatably mounted on the first mounting portion. The second positioning block is rotatably and slidably mounted on the second mounting portion. The elastic member has one end thereof mounted on the third mounting portion and the other end thereof mounted on the second positioning block. The elastic member is configured for biasing the second positioning portion to slide towards the first positioning block.

In another aspect, an external keypad assembly using the present positioning structure is provided. The external keypad assembly includes an upper shell and a lower shell. The lower shell is attached with the upper shell.

These and other aspects of the present invention will become more apparent from the following detailed description of the preferred embodiments taken in conjunction with the accompanying drawings, although variations and modifications therein may be affected without departing from the spirit and scope of the novel concepts of the disclosure.

### BRIEF DESCRIPTION OF THE DRAWINGS

Many aspects of the present positioning structure for a keypad assembly can be better understood with reference to the following drawings. These drawings are not necessarily drawn to scale, the emphasis instead being placed upon clearly illustrating the principles of the present positioning structure and the present keypad assembly. Moreover, in the drawings like reference numerals designate corresponding parts throughout the several views. Wherever possible, the same reference numbers are used throughout the drawings to refer to the same or like elements of an embodiment.

FIG. 1 is an isometric view of an accessory keypad assembly positioned on a portable electronic device in accordance with a present embodiment.

FIG. 2 is another isometric view of the accessory keypad assembly and the portable electronic, showing another aspect thereof.

FIG. 3 is an exploded view of the accessory keypad assembly shown in FIG. 1 and FIG. 2.

FIG. 4 is another exploded view of the accessory keypad assembly shown in FIG. 1 and FIG. 2.

FIG. 5 is an assembled view of the accessory keypad assembly shown in FIG. 3 and FIG. 4, the accessory keypad assembly being in a clamping status.

FIG. 6 is another assembled view of the accessory keypad assembly shown in FIG. 3 and FIG. 4, the accessory keypad assembly being in a unclamping status.

FIG. 7 is a cut-away view of the accessory keypad assembly shown in FIG. 5.

### DETAILED DESCRIPTION OF THE EMBODIMENTS

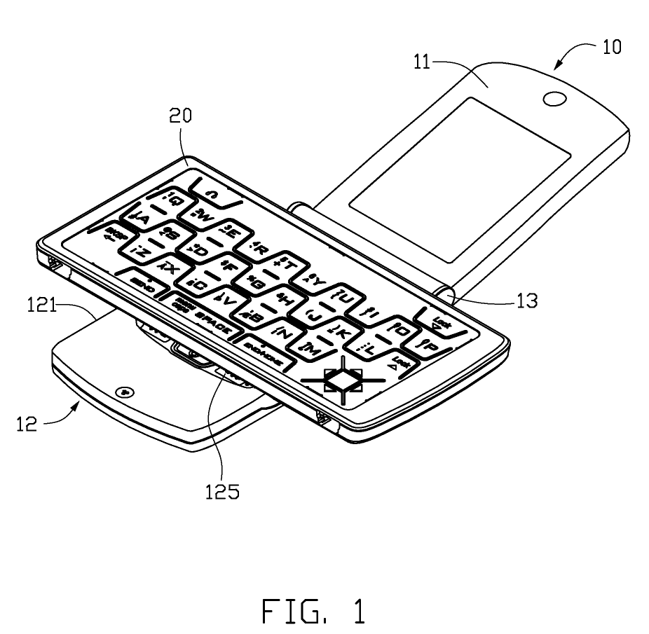

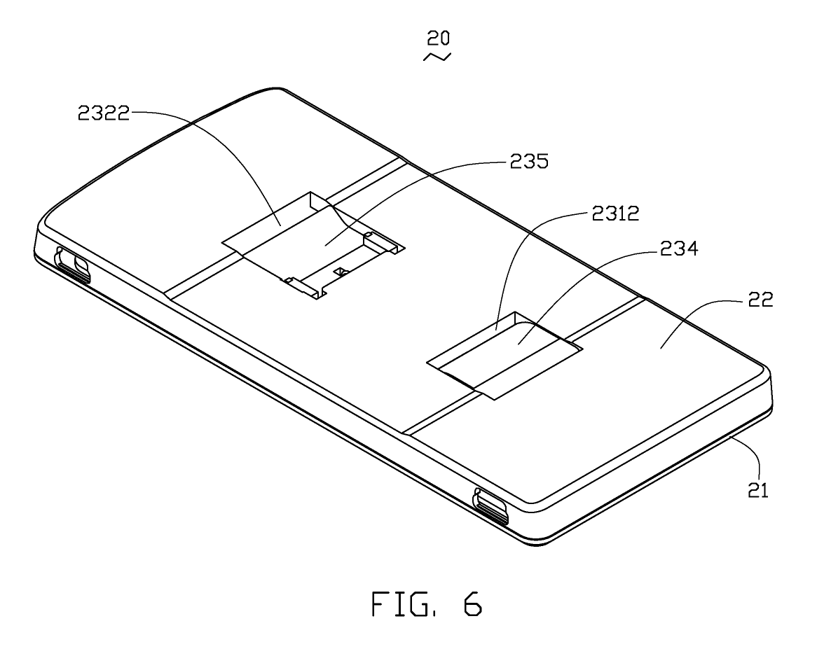

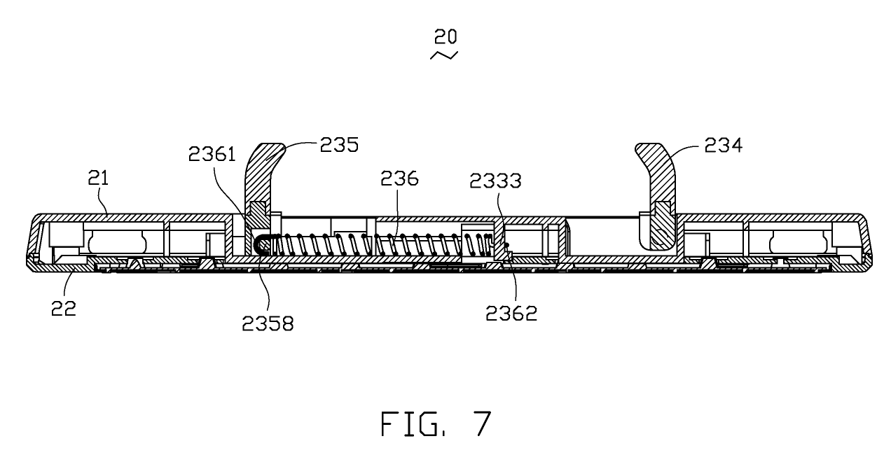

The present positioning structure 23 for an external keypad assembly 20 is described here in conjunction with the accompanying drawings in FIGS. 1 through 7. The external keypad assembly 20 using the positioning structure 23 is suitably positioned on a portable electronic device 1 0, such as a mobile phone, a personal digital handset, or the like.

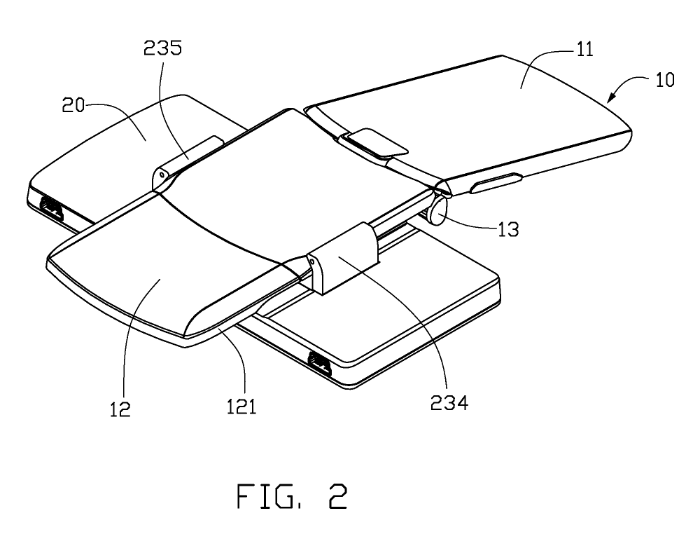

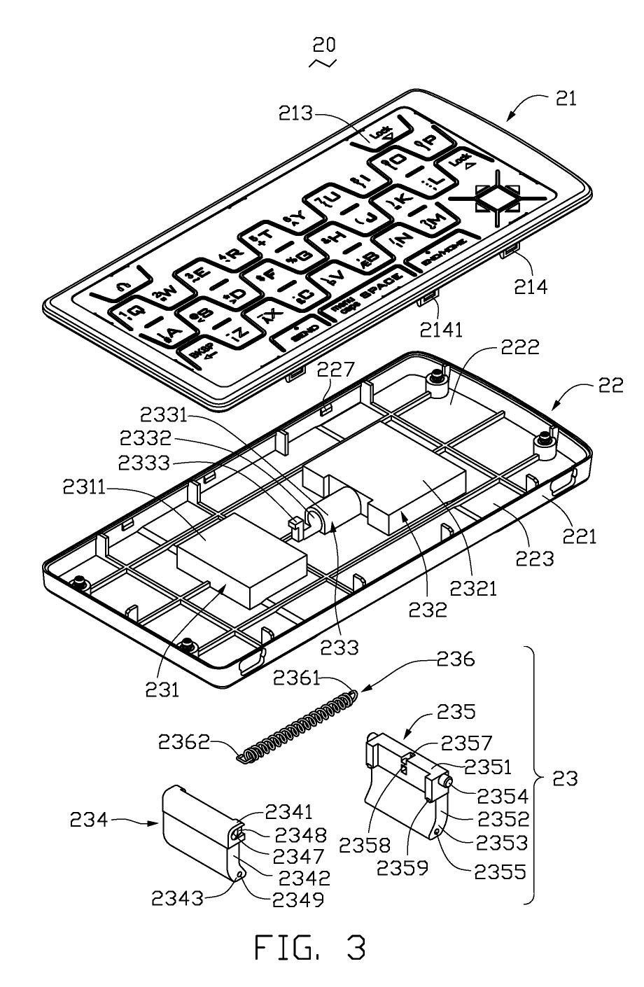

Referring to FIGS. 1 and 2, the portable electronic device 10 includes a lid body 11, a base body 12, and a hinge 13 rotatably connecting the base body 12 and the lid body 11. A main keypad assembly 125 is assembled with the base body 12 and has a plurality of key buttons 213 (seen in FIG. 3) exposed on an upper surface of the base body 12. The base body 12 further has two opposite sidewalls 121 thereof, which facilitates the positioning/clamping of external keypad assembly 20 with the base body 12.

The external keypad assembly 20 is a keyboard positioned with the base body 12, which communicates with the portable electronic device 10 with wires/cables or wirelessly (e.g., Bluetooth wireless transmission technology). In use, due to the size of the external keypad assembly 20 is larger than that of the main keypad assembly 125, operator may operate the external keypad assembly 20 more easily than the main keypad assembly 125.

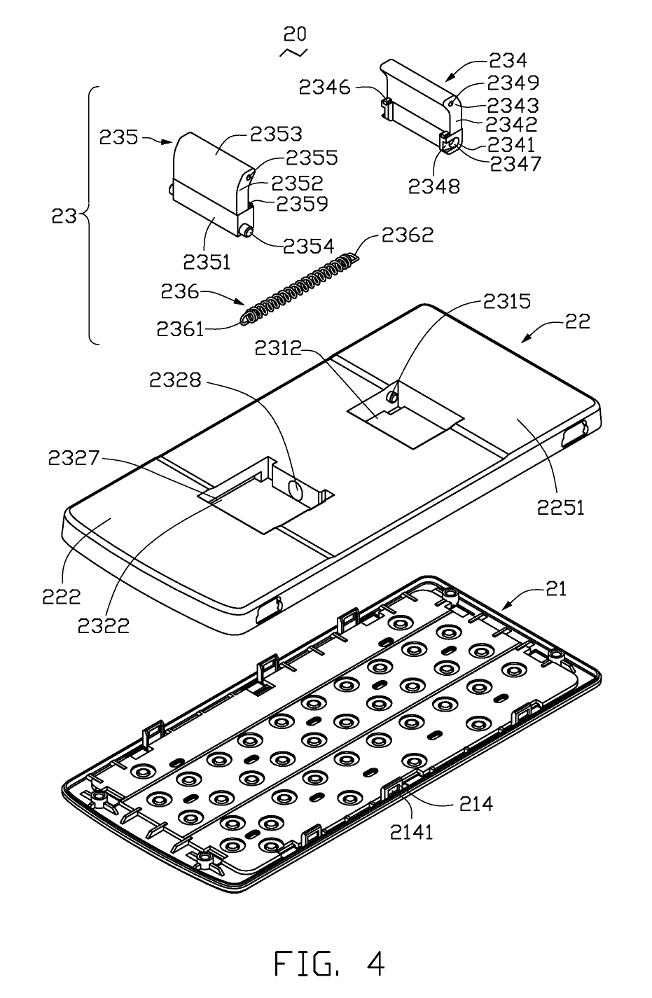

Referring further to FIG. 3 and FIG. 4, the external keypad assembly 20 includes an upper shell 21, a lower shell 22, and the positioning structure 23. The positioning structure 23 is configured (i.e., structured/arranged) for positioning the external keypad assembly 20 on the base body 12 of the portable electronic device 10.

The upper shell 21 has a plurality of key buttons 213 disposed on one surface thereof and six latching portions 214 disposed on another surface thereof. The six latching portions 214 are located on the opposite side of the key buttons 213. The six latching portions 214 are rectangular-shaped and each has a rectangular latching groove 2141 defined therethrough.

The lower shell 22 is configured to attach with the upper shell 21 thus, cooperatively enclose a receiving space (not labeled) therewithin. The lower shell 22 is generally a rectangular shell and has four sidewalls 221 and an enclosed wall 222 cooperatively defining an accommodating space 223 therein. Two facing sidewalls has six latching claws 227 corresponding to the six latching portions 214 of the upper shell 21, respectively. The six latching claws 227 each is configured for latching/hooking with respective latching portion 214 via engaging into the latching groove 2141 of the latching portion 214.

The positioning structure 23 includes a first mounting portion 231, a second mounting portion 232, a third mounting portion 233, a first positioning block 234, a second positioning block 235, and an elastic member 236. The first mounting portion 231 and the second mounting portion 232 are formed on the lower shell 22 of the external keypad assembly 20. The third mounting portion 233 extends from the second mounting portion 232 and located between the first mounting portion 231 and second mounting portion 232. The first positioning block 234 is rotatably mounted on the first mounting portion 231. The second positioning block 235 is rotatably and slidably mounted on the second mounting portion 232. The elastic member 236 has one end thereof mounted on the third mounting portion 233 and the other end thereof mounted on the second positioning block 235. The elastic member 236 is configured for biasing the second positioning block 235 to slide towards the first positioning block 234.

The first mounting portion 231 includes a first accommodating cavity 2312 and two shaft portions 2315. The first accommodating cavity 2312 is generally rectangular and configured for accommodating the first positioning block 234 therein. The first accommodating cavity 2312 is defined through the enclosed wall 222 of the lower shell 22 into a first protruding portion 2311 protruded from the enclosed wall 222. The two shaft portions 231 5 are generally cylindrical and oppositely disposed within the first accommodating cavity 2312. The first accommodating cavity 2312 is enclosed by four sidewalls, and the two shaft portions 2315 are protruded from two opposite sidewalls and located in alignment with each other within the first accommodating cavity 2312.

The second mounting portion 232 includes a second accommodating cavity 2322 and two sliding grooves 2327. The second accommodating cavity 2322 is generally rectangular and configured for accommodating the second positioning block 235 therein. The second accommodating cavity 2322 is defined through the enclosed wall 222 of the lower shell 22 into a second protruding portion 2321 protruded from the enclosed wall 222. The second accommodating cavity 2322 is enclosed by four sidewalls, and the two sliding grooves 2327 are defined in two opposite sidewalls and aligned with each other. The two sliding grooves 2327 are oppositely defined communicating with the second accommodating cavity 2322.

The third mounting portion 233 is generally a cylinder 2331 with a Z-shaped first hooked portion 2333 extending therefrom. The cylinder 2331 connects with the first protruding portion 2311 and is located between the first protruding portion 2311 and the second protruding portion 2321. The third mounting portion 233 further defines a through aperture 2332 through the cylinder 2331. The through aperture 2332 communicates with the second accommodating cavity 2322. The first hooked portion 2333 extends towards the second protruding portion 2321 in alignment with the through aperture 2332.

The first positioning block 234 includes a first base portion 2341 and a first clamping claw 2342 extending from the first base portion 2341. The first base portion 2341 defines two shaft holes 2347 and two mounting grooves 2348 respectively communicating with the two shaft holes 2347. The two shaft holes 2347 respectively correspond with the two shaft portions 2315 of the first mounting portion 231. The two mounting grooves 2348 each is configured for facilitating each shaft portions 231 5 engaging into corresponding shaft hole 2347. The first base portion 2341 further includes two first resisting portions 2346 protruded from a surface from which the first clamping claw 2342 extends the first base portion 2341.

The first clamping claw 2342 includes an arc-shaped first claw portion 2343 and at least one first retaining portions 2349 formed on the first claw portion 2343. The arc-shaped first claw portion 2343 is configured for facilitating clamping of the first positioning block 234 with the base body 12 of the portable electronic device 10. The at least one first retaining portions 2349 is configured for elastically resisting against the sidewall of the first accommodating cavity 2312 and thus retaining the first positioning block 234 in the first accommodating cavity 2312.

The second positioning block 235 includes a second base portion 2351 and a second clamping claw 2352 extending from the second base portion 2351. The second base portion 2351 has two protruding posts 2354 protruded corresponding with the two sliding grooves 2327 of the second mounting portion 232. The two protruding posts 2354 respectively engage into the two sliding grooves 2327 and are configured for rotatably and slidably moving in the two sliding grooves 2327. The second base portion 2351 further has a second hooked portion 2358 formed thereon and two second resisting portions 2359 protruded from a surface which the second clamping claw 2352 extends from the second base portion 2351. The second hooked portion 2358 is formed by defining an intersecting aperture 2357. The intersecting apertures 2357 is defined in one corner side of the second base portion 2351, as clearly seen in FIG. 3, with two horizontally defined slits and one vertically defined slit communicating with the two horizontally defined slits.

The second clamping claw 2352 includes an arc-shaped second claw portion 2353 and at least one second retaining portions 2355 formed on the second claw portion 2353. The arc-shaped second claw portion 2353 is configured for facilitating clamping of the second positioning block 235 with the base body 12 of the portable electronic device 10. The at least one second retaining portions 2355 is configured for elastically resisting against the sidewall of the second accommodating cavity 2322 and thus retaining the second positioning block 235 in the second accommodating cavity 2322.

The elastic member 236 is advantageously a coil spring, which has a first hooked end 2361 and a second hooked end 2362 formed on two opposite ends thereof. The elastic member 236 is configured for engaging through the through aperture 2332 of the third mounting portion 233 so as to hook the first hooked end 2361 with the first hooked portion 2333 of the third mounting portion 233 and hook the second hooked end 2362 with the second hooked portion 2358 of the second positioning block 235.

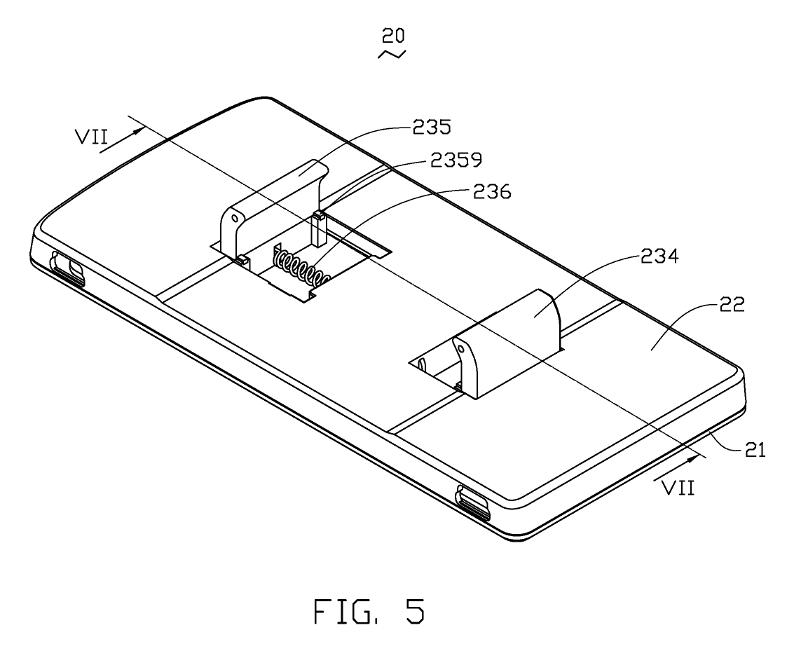

In assembly, referring further to FIGS. 5 through 7, the second hooked end 2362 of the elastic member 236 is hooked with the first hooked portion 2333 of the third mounting portion 233 of the lower shell 22. Meanwhile, the elastic member 236 is inserted through the through aperture 2332 of the third mounting portion 233 with the first hooked end 2361 thereof exposing in the second accommodating cavity 2322 of the second mounting portion 232 of the lower shell 22. The second positioning block 235 is inserted into the second accommodating cavity 2322. As such, the first hooked end 2361 is hooked with the second hooked portion 2358 of the second positioning block 235. The second positioning block 235 is thus positioned in the second accommodating cavity 2322 with the two protruding posts 2354 thereof engaging into the respective sliding groove 2327 of the second mounting portion 232.

After that, the first positioning block 234 is positioned in the first accommodating cavity 2312 of the first mounting portion 231 of the lower shell 22 in such manner that the two shaft portions 231 5 each engages into the respective mounting groove 2348 of the first positioning block 234 then, slide along the mounting groove 2348 to engage into the corresponding shaft hole 2347 of the first positioning block 234.

The lower shell 22, combined with the first positioning block 234, the second positioning block 235, and the elastic member 236, is further attached with the upper shell 21 by respective latching of the latching claws 227 with the latching portions 214. Thus, assembly of the accessory keypad assembly 20 is completed.

In positioning the external keypad assembly 20 on the portable electronic device 10, the first positioning block 234 and the second positioning block 235 are firstly rotated with respect to the external keypad assembly 20 so as to expose the first claw portion 2343 and the second claw portion 2353 from the first accommodating cavity 2312 and the second accommodating cavity 2322. Secondly, the second positioning block 235 is pulled away from the first positioning block 234 along the two sliding grooves 2327 of the second mounting portion 232. In this case, the elastic member 236 is accordingly stretched. Thirdly, the external keypad assembly 20 is placed above the main keypad assembly 125 of the portable electronic device 10 with the first claw portion 2343 and the second claw portion 2353 aligned with the two sidewalls 121 of the base body 12 of the portable electronic device 10. Finally, the second claw portion 2353 of the second positioning block 235 is released then moves towards one sidewall 121 by the restoring force of the elastic member 236 so as to clamp the base body 12 with the first claw portion 2343 of the first positioning block 234. Thus, the accessory keypad assembly 20 is positioned on the portable electronic device 10.

One main advantage of the present embodiment embodies that the external keypad assembly 20 can be securely/stably positioned on the portable electronic device 10 by clamping of the first positioning block 234 and the second positioning block 235 with the base body 12. As user operates the external keypad assembly 20, unstable movements and/or shakings of the external keypad assembly 20 relative to the main keypad assembly 21 may be avoided effectively.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A positioning structure for an accessory keypad assembly which includes an upper shell and a lower shell, the positioning structure comprising:
a first mounting portion defined in the lower shell of the keypad assembly;
a second mounting portion defined in the lower shell of the keypad assembly;
a third mounting portion extending from the second mounting portion and located between the first mounting portion and the second mounting portion;
a first positioning block rotatably mounted on the first mounting portion;
a second positioning block rotatably and slidably mounted on the second mounting portion; and
an elastic member with one end thereof mounted on the third mounting portion and the other end thereof mounted on the second positioning block, the elastic member configured for biasing the second positioning portion to slide towards the first positioning block.

2. The positioning structure as claimed in claim 1, wherein the first mounting portion comprises a first accommodating cavity and two shaft portions, the first accommodating cavity configured for accommodating the first positioning block therein, the two shaft portions being oppositely disposed within the first accommodating cavity, the first positioning block comprising a first base portion, the first base portion defining two shaft holes corresponding with the two shaft portions, and the two shaft portions respectively engaging into the two shaft holes.

3. The positioning structure as claimed in claim 2, wherein the first accommodating cavity is enclosed by four sidewalls, the two shaft portions are formed on opposite two of the four sidewalls and aligned with each other.

4. The positioning structure as claimed in claim 2, wherein the first positioning block further comprises a first clamping claw extending from the first base portion, the first clamping claw comprising a first claw portion configured for facilitating a clamping of the first positioning block.

5. The positioning structure as claimed in claim 4, wherein the first clamping claw further comprises at least one retaining portion formed on the first claw portion, the at least one retaining portion being configured for retaining the first positioning block in the first accommodating cavity.

6. The positioning structure as claimed in claim 4, wherein the first base portion further comprises two first resisting portions, the two resisting portions being protruded from a surface from which the first clamping claw extends to the first base portion.

7. The positioning structure as claimed in claim 2, wherein the first base portion further comprises two mounting grooves, the two mounting grooves respectively communicating with the two shaft holes, and the two mounting grooves each being configured for facilitating each shaft portions engaging into corresponding shaft hole.

8. The positioning structure as claimed in claim 2, wherein the second mounting portion comprises a second accommodating cavity and two sliding grooves, the second accommodating cavity configured for accommodating the second positioning block therein, the two sliding grooves being oppositely defined and communicating with the second accommodating cavity, the second positioning block comprising two protruding posts corresponding to the two sliding grooves, the two protruding posts respectively engaging into the two sliding grooves and configured for rotatably and slidably moving in the two sliding grooves.

9. The positioning structure as claimed in claim 8, wherein the second accommodating cavity is enclosed by four sidewalls, and the two sliding grooves are defined in two opposite one of the four sidewalls and aligned with each other.

10. The positioning structure as claimed in claim 8, wherein the second positioning block further comprises a second base portion and a second clamping claw extending from the second base portion, the second clamping claw comprising a second claw portion configured for facilitating clamping of the second positioning block.

11. The positioning structure as claimed in claim 8, wherein the second clamping claw further comprises at least one retaining portions formed on the second claw portion, the at least one retaining portions being configured for retaining the second positioning block in the second accommodating cavity.

12. The positioning structure as claimed in claim 8, wherein the third mounting portion comprises a through aperture defined therethrough and a first hooked portion, the through aperture communicating with the second accommodating cavity, the second positioning block further comprising a second base portion, the second base portion forming a second hooked portion, the elastic member configured for mounting one end thereof on the first hooked portion and engaging through the through aperture to mount the other end thereof on the second hooked portion.

13. The positioning structure as claimed in claim 12, wherein the first hooked portion is aligned with the through aperture.

14. The positioning structure as claimed in claim 12, wherein the elastic member comprises a first hooked end and a second hooked end, the first hooked end being hooked with the first hooked portion, the second hooked end being hooked with the second hooked portion.

15. An accessory keypad assembly for a portable electronic device, comprising:
an upper shell;
a lower shell attached with the upper shell; and
a positioning structure, comprising:
a first mounting portion defined in the lower shell of the keypad assembly;
a second mounting portion defined in the lower shell of the keypad assembly;
a third mounting portion extending from the second mounting portion and located between the first mounting portion and second mounting portion;
a first positioning block rotatably mounted on the first mounting portion;
a second positioning block rotatably and slidably mounted on the second mounting portion; and
an elastic member with one end thereof mounted on the third mounting portion and the other end thereof mounted on the second positioning block, the elastic member configured for biasing the second positioning portion to slide towards the first positioning block.
